(19) United States
(12) Patent Application Publication
(10) Pub. No.: US 2024/0387560 A1
(43) Pub. Date: Nov. 21, 2024

(54) ARRAY SUBSTRATE AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Yadong ZHANG, Beijing (CN); Yangjun LEI, Beijing (CN); Xiongcan ZUO, Beijing (CN); Bo WU, Beijing (CN); Ting LI, Beijing (CN); Chunmiao TANG, Beijing (CN); Yongju YANG, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/273,032

(22) PCT Filed: Sep. 19, 2022
(86) PCT No.: PCT/CN2022/119699

§ 371 Date: Jul. 19, 2023

(51) Int. Cl. H01L 27/12; G02F 1/1362; G02F 1/1368

(52) U.S. Cl. CPC H01L 27/124; G02F 1/136286; G02F 1/1368

(57) ABSTRACT

Provided is an array substrate, including: a substrate including a display region, a wiring region, and a circuit region that are successively adjacent; a plurality of pixels disposed in the display region; a common electrode line disposed in the wiring region and including a plurality of cutouts spaced apart; a plurality of gate lines disposed in the display region and the wiring region; a plurality of gate leads disposed in the circuit region and the wiring region; and a gate drive circuit, disposed in the circuit region and coupled to the plurality of gate leads, wherein the plurality of gate leads are connected to the plurality of gate lines by a connection portion disposed within the cutout, and the plurality of gate lines are coupled to the plurality of pixels.

### CROSS-REFERENCE TO RELATED APPLICATION

The present disclosure is a U.S. national stage of international application No. PCT/CN2022/119699, filed on Sep. 19, 2022, the content of which is herein incorporated by reference in its entirety.

### TECHNICAL FIELD

The present disclosure relates to the field of display technologies, and in particular, relates to an array substrate and a display device.

### BACKGROUND OF THE INVENTION

Thin film transistor-liquid crystal display (TFT-LCD) devices are commonly used in the display field.

### SUMMARY OF THE INVENTION

Embodiments of the present disclosure provide an array substrate and a display device. the technical solutions are as follows.

According to some embodiments of the present disclosure, an array substrate is provided. The array substrate includes:
a substrate, including a display region, a wiring region, and a circuit region, wherein the wiring region and the circuit region are disposed on at least one side of the display region and successively arranged along a direction away from the display region;
a plurality of pixels, disposed in the display region;
a common electrode line, extending along a first direction and disposed in the wiring region, wherein the common electrode line includes a plurality of cutouts spaced apart and is coupled to the plurality of pixels;
a plurality of gate lines, extending along a second direction and disposed in the display region and the wiring region, wherein the first direction is intersected with the second direction;
a plurality of gate leads, extending along the second direction and disposed in the circuit region and the wiring region, wherein the plurality of gate leads are disposed on a side, distal from the substrate, of the gate line and a side, proximal to the substrate, of the common electrode line; and
a gate drive circuit, disposed in the circuit region and coupled to the plurality of gate leads, wherein the plurality of gate leads are connected to the plurality of gate lines by a connection portion disposed within the cutout, and the plurality of gate lines are coupled to the plurality of pixels.

In some embodiments, an edge of each of the cutouts is spaced from an edge of the common electrode line, and the edges of the cutouts are equally spaced from any edge, in the second direction, of the common electrode line; and the plurality of cutouts are spaced apart along the first direction.

In some embodiments, the gate drive circuit includes: a plurality of shift register units that are successively arranged and cascaded along the first direction, and the plurality of pixels are arranged in arrays; wherein the plurality of shift register units are coupled to the plurality of gate leads in one-to-one correspondence, the plurality of gate leads are connected to the plurality of gate lines in one-to-one correspondence by connection portions disposed within the plurality of cutouts in one-to-one correspondence, and the plurality of gate lines are coupled to a plurality of rows of the pixels in one-to-one correspondence.

In some embodiments, each of the gate leads, each of the cutouts, and each of the gate lines, which are in one-to-one correspondence, are successively arranged in the second direction along the same horizontal line.

In some embodiments, the array substrate further includes: a first insulator layer disposed between the gate line and the gate lead; a second insulator layer disposed on a side, distal from the substrate, of the gate lead; a first connection portion disposed on a side, distal from the substrate, of the second insulator layer; and a plurality of first vias running through the second insulator layer, and a plurality of second vias running through the second insulator layer and the first insulator layer; wherein an orthographic projection of the gate lead on the substrate is within an orthographic projection of the gate line on the substrate, and orthographic projections of the plurality of first vias on the substrate are not overlapped with orthographic projections of the plurality of second vias on the substrate; and the first connection portion is lapped to the gate lead through the plurality of first vias and lapped to the gate line through the plurality of second vias, such that the gate line is connected to the gate lead.

In some embodiments, a number of the plurality of first vias is equal to a number of the plurality of second vias.

In some embodiments, a number of the plurality of first vias and a number of the plurality of second vias are both greater than or equal to four and less than or equal to eight.

In some embodiments, the plurality of first vias are organized into a plurality of first via groups successively arranged along the first direction, wherein each of the first via groups includes a plurality of the first vias successively arranged along the second direction, and a number of the first vias in each of the first via groups is less than or equal to a number of the plurality of first via groups; and the plurality of second vias are organized into a plurality of second via groups successively arranged along the first direction, wherein each of the second via groups includes a plurality of the second vias successively arranged along the second direction, and a number of the second vias in each of the second via groups is less than or equal to a number of the plurality of second via groups.

In some embodiments, the number of the plurality of first vias and the number of the plurality of second vias are both four; the plurality of first vias (K1) are organized into two of the first via groups successively arranged along the first direction, and each of the first via groups includes two of the first vias successively arranged along the second direction; and the plurality of second vias are organized into two of the second via groups successively arranged along the first direction, and each of the second via groups includes two of the second vias successively arranged along the second direction.

In some embodiments, the first connection portion and the common electrode line are disposed in the same layer.

In some embodiments, the array substrate further includes: a common electrode lead disposed in the wiring region, wherein the common electrode lead includes: a first electrode line and a second electrode line that are disposed between the substrate and the common electrode line and successively stacked along a direction away from the substrate; and the array substrate further includes: a third insulator layer disposed between the first electrode line and the second electrode line, and a fourth insulator layer disposed between the second electrode line and the common electrode line; wherein the common electrode line is lapped to the second electrode line through a via running through the fourth insulator layer, and is lapped to the first electrode line through a via running through the third insulator layer and the fourth insulator layer, such that the common electrode line receives common signals from the first electrode line and the second electrode line.

In some embodiments, the first electrode line includes a plurality of first electrode blocks spaced apart, and the second electrode line includes a plurality of second electrode blocks spaced apart.

In some embodiments, the pixel includes: a gate metal layer, a gate insulator layer, a source-drain metal layer, a passivation layer, and an electrode layer that are successively stacked along the direction away from the substrate; wherein the first electrode line and the gate line are disposed in the same layer, and are both disposed in the same layer as the gate metal layer; the second electrode line and the gate lead are disposed in the same layer, and are both disposed in the same layer as the source-drain metal layer; the first insulator layer and the third insulator layer are disposed in the same layer, and are both disposed in the same layer as the gate insulator layer; the second insulator layer and the fourth insulator layer are disposed in the same layer, and are both disposed in the same layer as the passivation layer; and the common electrode line and the electrode layer are disposed in the same layer.

In some embodiments, each of the shift register units in the gate drive circuit includes: an input circuit and an output circuit; wherein the input circuit is coupled to a plurality of drive signal lines and a pull-up node, and is configured to charge the pull-up node in response to drive signals from the plurality of drive signal lines; and the output circuit is coupled to the pull-up node and the gate lead, and is configured to transmit a gate drive signal to the gate lead based on a potential of the pull-up node.

In some embodiments, the input circuit, the output circuit, and the plurality of drive signal lines include: a gate metal layer, a gate insulator layer, a source-drain metal layer, and a passivation layer that are successively stacked along the direction away from the substrate; and the array substrate further includes: a second connection portion disposed on a side, distal from the substrate, of the passivation layer, wherein the second connection portion is lapped to the source-drain metal layer through a plurality of third vias running through the passivation layer, and is lapped to the gate metal layer through a plurality of fourth vias running through the passivation layer and the gate insulator layer, such that the input circuit is coupled to the drive signal line at a coupling node, and the input circuit is coupled to the output circuit at the pull-up node; wherein an orthographic projection of the source-drain metal layer on the substrate is within an orthographic projection of the gate metal layer on the substrate, and orthographic projections of the plurality of third vias on the substrate are not overlapped with orthographic projections of the plurality of fourth vias on the substrate; wherein a number of the third vias that are run through for coupling at the pull-up node is greater than a number of the third vias that are run through for coupling at the coupling node, and a number of the fourth vias that are run through for coupling at the pull-up node is greater than a number of the fourth vias that are run through for coupling at the coupling node.

In some embodiments, the number of the third vias that are run through for coupling at the pull-up node is equal to the number of the fourth vias that are run through for coupling at the pull-up node; and the number of the third vias that are run through for coupling at the coupling node is equal to the number of the fourth vias that are run through for coupling at the coupling node.

In some embodiments, the number of the third vias that are run through for coupling at the pull-up node and the number of the fourth vias that are run through for coupling at the pull-up node are both greater than or equal to three and less than or equal to six; and the number of the third vias that are run through for coupling at the coupling node and the number of the fourth vias that are run through for coupling at the coupling node are both less than or equal to two.

In some embodiments, a plurality of the third vias that are run through for coupling at the pull-up node and a plurality of the third vias that are run through for coupling at the coupling node are organized into a plurality of third via groups successively arranged along the second direction, wherein each of the third via groups includes one of the third vias; and a plurality of the fourth vias that are run through for coupling at the pull-up node and a plurality of the fourth vias that are run through for coupling at the coupling node are organized into a plurality of fourth via groups successively arranged along the second direction, wherein each of the fourth via groups includes one of the fourth vias; wherein the third via groups and the fourth via groups are successively arranged along the first direction.

In some embodiments, a number of the plurality of the third vias that are run through for coupling at the pull-up node and a number of the plurality of the fourth vias that are run through for coupling at the pull-up node are both three; and a number of the plurality of the third vias that are run through for coupling at the coupling node and a number of the plurality of the fourth vias that are run through for coupling at the coupling node are both two; the plurality of the third vias that are run through for coupling at the pull-up node are organized into three of the third via groups successively arranged along the second direction, and the plurality of the fourth vias that are run through for coupling at the pull-up node include three of the fourth via groups successively arranged along the second direction; and the plurality of the third vias that are run through for coupling at the coupling node are organized into two of the third via groups successively arranged along the second direction, and the plurality of the fourth vias that are run through for coupling at the coupling node include two of the fourth via groups successively arranged along the second direction.

In some embodiments, the second connection portion and the common electrode line are disposed in the same layer.

In some embodiments, the first direction is perpendicular to the second direction.

According to some embodiments of the present disclosure, a display device is provided. The display device includes a power supply assembly and an array substrate as described above; wherein the power supply assembly is coupled to the array substrate and is configured to supply power to the array substrate.

In some embodiments, the display device includes an in-vehicle display device.

### BRIEF DESCRIPTION OF DRAWINGS

For clearer descriptions of the technical solutions in the embodiments of the present disclosure, the following briefly introduces the accompanying drawings to be required in the descriptions of the embodiments. Apparently, the accompanying drawings in the following description show merely some embodiments of the present disclosure, and persons of ordinary skills in the art may still derive other drawings from these accompanying drawings without creative efforts.

FIG. 1 is a schematic structural diagram of an array substrate according to some embodiments of the present disclosure;

FIG. 2 is a schematic sectional diagram of the structure illustrated in FIG. 1 in a direction a1-a2;

FIG. 3 is a schematic structural diagram of another array substrate according to some embodiments of the present disclosure;

FIG. 4 is another schematic sectional diagram of the structure illustrated in FIG. 1 in a direction a1-a2;

FIG. 5 is a top view of partial regions of the structure illustrated in FIG. 4;

FIG. 6 is a schematic structural diagram of still another array substrate according to some embodiments of the present disclosure;

FIG. 7 is a schematic sectional diagram of the structure illustrated in FIG. 6 in a direction b1-b2;

FIG. 8 is a schematic sectional diagram of the structure illustrated in FIG. 6 in a direction c1-c2;

FIG. 9 is a schematic sectional diagram of a pixel in a display region according to some embodiments of the present disclosure;

FIG. 10 is a schematic structural diagram of a shift register unit according to some embodiments of the present disclosure;

FIG. 11 is a schematic sectional diagram of a shift register unit according to some embodiments of the present disclosure;

FIG. 12 is a schematic diagram of an analog voltage according to some embodiments of the present disclosure;

FIG. 13 is a structural layout of a shift register unit according to some embodiments of the present disclosure;

FIG. 14 is a top view of different nodes of the structure illustrated in FIG. 13;

FIG. 15 is a flowchart of a method for preparing an array substrate according to some embodiments of the present disclosure; and

FIG. 16 is a schematic structural diagram of a display device according to some embodiments of the present disclosure.

### DETAILED DESCRIPTION

The present disclosure is described in further detail with reference to the accompanying drawings, to clearly present the objects, technical solutions, and advantages of the present disclosure.

In the related art, an array substrate in the TFT-LCD device includes: a substrate including a display region and a non-display region, a thin film transistor (TFT) and an electrode that are disposed in the display region, a common electrode line and a gate drive circuit that are disposed in the non-display region and successively arranged in a direction away from the display region, and a gate lead and a gate line that are disposed in the display region and the non-display region and disposed in different layers. The common electrode line is coupled to the electrode and supplies a drive signal to the electrode. The gate drive circuit is coupled to the TFT by the gate lead and the gate line and supplies a gate drive signal to the TFT. Because the gate lead and the gate line are disposed in different layers, the gate lead and the gate line need to be connected to each other via a connection hole.

However, due to layout of the connection holes and the common electrode lines, in the current array substrate, the non-display region occupies a large area of the substrate, which is not conducive to a narrow frame design of the array substrate.

A display effect of a whole array substrate is poor as a result of a large frame of the array substrate, and a visual effect of the whole array substrate is also poor. Therefore, with the development of the display technology, the display effect is improved by compressing the frame of the array substrate (i.e., designing an array substrate with a narrow frame), which satisfies the user's demand for the display effect. The narrow frame is implemented by integrating a gate drive circuit onto a substrate using a gate drive on array (GOA) technique. The gate drive circuit is also referred to as a GOA circuit. However, as described above, the narrow frame design is not reliably achieved due to the layout of the common electrode lines and the layout of the connection holes (i.e., connection portions) of the gate lines and the gate leads, wherein the gate lines and the gate leads are configured to couple the GOA circuit to the TFT.

Some embodiments of the present disclosure provide a new array substrate, in which layout of connection portions and common electrode lines is reasonably optimized, such that an area of a non-display region is extremely compressed, which facilitates a narrow frame design of the array substrate, and thus the user's demand for narrow frames is satisfied.

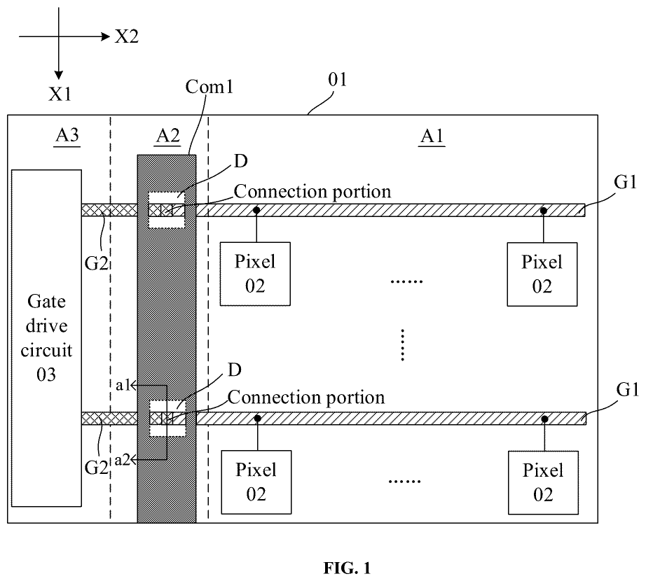

FIG. 1 is a schematic structural diagram of an array substrate according to some embodiments of the present disclosure. As illustrated in FIG. 1, the array substrate includes a substrate 01. The substrate 01 has a display region A1, a wiring region A2, and a circuit region A3, wherein the wiring region A2 and the circuit A3 are disposed on at least one side of the display region A1 and successively arranged along a direction away from the display region A1. That is, on at least one side of the display region A1, the circuit region A3 is adjacent to and in contact with the wiring region A2, and the wiring region A2 is adjacent to and in contact with the at least one side of the display region A1. Accordingly, the wiring region A2 is disposed between the circuit region A3 and the display region A1. In some embodiments of the present disclosure, the wiring region A2 and the circuit region A3 are also referred to as a non-display region.

For example, referring to FIG. 1, the display region A1 of the illustrated substrate 01 is rectangular and has four sides. The substrate 01 includes the wiring region A2 and the circuit region A3 that are disposed on a left side of the rectangular display region A1 and successively arranged along the direction away from the display region A1. In some embodiments, referring to FIG. 1, the wiring region A2 and the circuit region A3 of the substrate 01 having the rectangular display region A1 are disposed on a right side, an upper side, and/or, a lower side of the display region A1. In some embodiments, the display region A1 is in other shapes, such as circular, oval, trapezoidal, or triangular.

It should be noted that FIG. 1 only schematically illustrates areas of each of the display region A1, the wiring region A2, and the circuit region A3. In actual products, the area of the display region A1 is generally large, and the areas of the wiring region A2 and the circuit region A3 are both small, which lays the foundation for the narrow frame design of the array substrate and ensures a good display effect. The area of each region herein refers to the area of the substrate 01 occupied by each region.

Referring to FIG. 1, the array substrate according to some embodiments of the present disclosure further includes: a plurality of pixels 02 disposed in the display region A1, a common electrode line Com1 extending along a first direction X1, a plurality of gate lines G1 extending along a second direction X2, a plurality of gate leads G2 extending along the second direction X2, and a gate drive circuit 03.

The common electrode line Com1 is disposed in the wiring region A2, and is coupled (i.e., electrically connected) to the plurality of pixels 02 and configured to supply common signals to the plurality of pixels 02. For example, the pixel 02 includes a common electrode, and the common electrode line Com1 is coupled to the common electrode and configured to supply the common signal to the common electrode. It should be noted that coupling between the common electrode line Com1 to the pixel 02 is not illustrated in FIG. 1. In addition, the common electrode line Com1 according to some embodiments of the present disclosure has a plurality of cutouts D spaced apart and running through the common electrode line Com1.

The plurality of gate lines G1 are disposed in the display region A1 and the wiring region A2. That is, a portion of each of the gate lines G1 is disposed in the display region A1 and another portion of that is disposed in the wiring region A2. The second direction X2 is intersected with the first direction X1. That is, the two directions are not parallel.

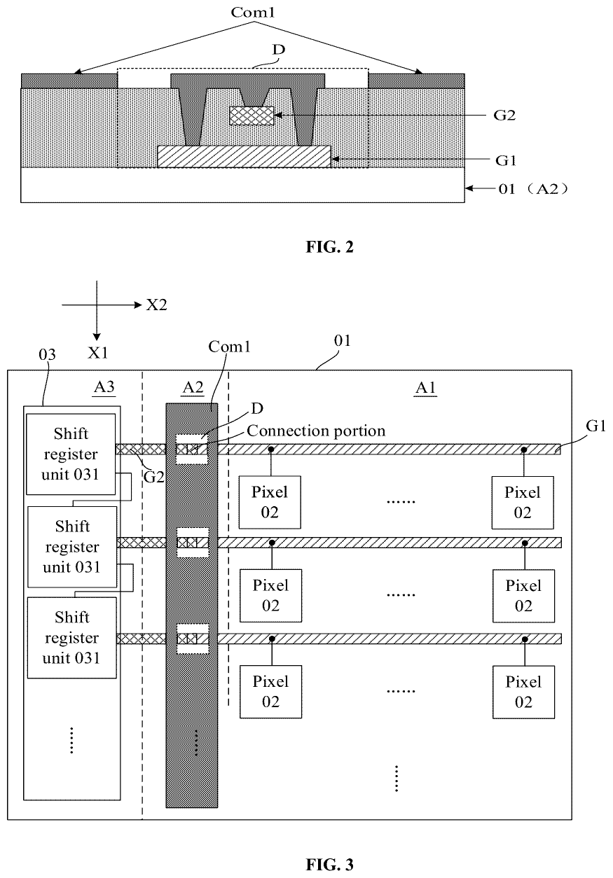

The plurality of gate leads G2 are disposed in the circuit region A3 and the wiring region A2. That is, a portion of each of the gate leads G2 is disposed in the circuit region A3 and another portion of that is disposed in the wiring region A2. Referring to the sectional diagram of FIG. 1 in the a1-a2 direction as illustrated in FIG. 2, the plurality of gate leads G2 are disposed on a side, distal from the substrate 01, of the gate line G1 and are disposed on a side, proximal to the substrate 01, of the common electrode line Com1. That is, in some embodiments of the present disclosure, the gate line G1, the gate lead G2, and the common electrode line Com1 are disposed in different layers and are successively stacked along the direction away from the substrate 01. In other embodiments, the position relationship between the gate line G1, the gate lead G2, and the common electrode line Com1 are changed. For example, the gate line G1 is disposed between the gate lead G2 and the common electrode line Com1.

The gate drive circuit 03 is disposed in the circuit region A3 and coupled to the plurality of gate leads G2. The plurality of gate leads G2 are connected to the plurality of gate lines G1, and the plurality of gate lines G1 are coupled to the plurality of pixels 02. That is, the gate drive circuit 03 is coupled to the pixel 02 by the gate lead G2 and the gate line G1 that are connected to each other. The gate drive circuit 03 is configured to supply gate drive signals to the plurality of pixels 02 by the plurality of gate leads G2 and the plurality of gate lines G1.

For example, the pixel 02 includes a TFT, and the gate drive circuit 03 is coupled to the TFT by the mutually connected gate lead G2 and gate line G1, such that the gate drive circuit 03 supplies the gate drive signal to the TFT and controls the TFT to turn on or turn off. In conjunction with the above description of the common electrode, the pixel 02 includes a pixel electrode and a liquid crystal molecule between the pixel electrode and the common electrode. In the case that the TFT is turned on, the pixel electrode is charged, and the liquid crystal molecule is deflected under a voltage difference between a voltage on the pixel electrode and a voltage on the common electrode, such that the pixel 02 is lit up. The array substrate including the pixel 02 is an LCD substrate.

Furthermore, referring to FIG. 1 and FIG. 2, in some embodiments of the present disclosure, a connection portion of the gate lead G2 and the gate line G1 that are disposed in different layers is within the cutout D. That is, the connection portion is within a region defined by the common electrode line Com1, and is also considered to be within the wiring region A2. An orthographic projection of the connection portion on the substrate 01 is overlapped with an orthographic projection of the common electrode line Com1 having the cutout D on the substrate 01. In this way, a space of the wiring region A2 is fully utilized, such that the non-display region including the wiring region A2 and the circuit region A3 occupies a smaller area of the substrate 01, which facilitates the narrow frame design of the array substrate.

In the related art, the connection portion of the gate lead G2 and the gate line G1 is generally disposed between the wiring region A2 and the circuit region A3. That is, the connection portion is disposed on a side, distal from the display region A1, of the wiring region A2, but is not in the wiring region A2. In this way, in one aspect, the space of the substrate 01 is not fully utilized and the narrow frame design fails to be achieved; and in another aspect, the connection portion is closer to a boundary of the substrate 01 where water vapor enters, as a consequence, the water vapor easily enters an effective line part and causes a problem of poor reliability, which is more obvious in scenarios with high temperature and humidity. There is a game that exists between the problem and some products that require strict reliability (e.g., in-vehicle display products).

Considering above problems, in the related art, the connection portion of the gate lead G2 and the gate line G1 is adjusted to be between the wiring region A2 and the display region A1. That is, he connection portion is disposed on a side, proximal to the display region A1, of the wiring region A2, but is not in the wiring region A2. However, because the connection portion is proximal to the display region A1, an electric field of the connection portion inevitably affects a drive electric field required to light up the pixel 02 in the display region A1. For example, an electric field driving the deflection of the liquid crystal molecules is affected, and thus the electric field driving the deflection of the liquid crystal molecules deviates from the normal voltage, which leads to abnormal luminescence, such as light leakage, of the pixel 02 proximal to the wiring region (i.e., an edge of the display region A1). As a consequence, the display effect of the array substrate is poor, and the product yield is low. For example, assuming that the plurality of pixels 02 include red pixels, green pixels, and blue pixels and the pixel 02 proximal to the wiring region A2 is the red pixel. In this case, the luminance of the red pixel is greater than the luminance of the green pixel and the luminance of the blue pixel, that is, the light leakage occurs to the red pixel.

In the embodiments of the present disclosure, by arranging the connection portion to be within the wiring region A2 and the cutout of the common electrode line Com1, the narrow frame design of the array substrate is better achieved as described in the above embodiments; the external water vapor is prevented from entering into the effective line part, which improves the product reliability; and the electric field of the connection portion is avoided from affecting the electric field within the display region A1, such that the light leakage problem is addressed, the display effect is improved, and the product yield is increased. In other words, by reasonably deploying the common electrode line Com1 and the connection portion of the gate line G1 and the gate lead G2, the frame is narrower and the light leakage at the edge of the array substrate is avoided under the prerequisite that the high reliability of the in-vehicle product is ensured. The array substrate according to some embodiments of the present disclosure is better applied to display products with narrow frames.

In summary, some embodiments of the present disclosure provide an array substrate. The array substrate includes the substrate including the display region, the wiring region, and the circuit region that are successively adjacent, the pixel disposed in the display region, the common electrode line disposed in the wiring region and including the cutout, the gate lead disposed in the wiring region and the circuit region, the gate line disposed in the wiring region and the display region, and the gate drive circuit disposed in the circuit region. In particular, the gate lead and the gate line are disposed in different layers and connected to each other; the gate drive circuit is coupled to the pixel by the mutually connected gate lead and the gate line and supplies the gate drive signal to the pixel; and the common electrode line is coupled to the pixel and supplies the common signal to the pixel. Because the connection portion of the gate lead and the gate line is within the cutout of the common electrode line, that is, within the wiring region, the space is fully utilized, such that the area of the substrate occupied by other portions other than the display region is small, which facilitates the narrow frame design of the array substrate.

In some embodiments, referring to FIG. 1, the first direction X1 and the second direction X2 described in some embodiments of the present disclosure are perpendicular to each other.

In some embodiments, referring to FIG. 1, the plurality of cutouts D are spaced apart along the first direction X1. An edge of each of the cutouts D of the common electrode line Com1 is spaced from an edge of the common electrode line Com1, and the edges of the cutouts D are equally spaced from any edge, in the second direction X2, of the common electrode line Com1. That is, each of the cutouts D is surrounded by a rest, other than the cutout D, of the common electrode line Com1. On the basis that the common electrode line Com1 and the cutout D are both rectangular as illustrated in FIG. 1, in the first direction X1, a center axis of each of the cutouts D is overlapped with a center axis of the common electrode line Com1 and is disposed at a center of the common electrode line Com1. In this way, the layout is more regular and the product reliability is better improved, and the display effect of the array substrate is improved and the product yield is increased.

In some embodiments, based on FIG. 1, referring to a schematic structural diagram of another array substrate as illustrated in FIG. 3, the gate drive circuit 03 includes a plurality of shift register units 031 successively arranged and cascaded along the first direction X1. The shift register unit 031 is referred to as a GOA unit.

The plurality of pixels 02 according to some embodiments of the present disclosure are arranged in arrays. That is, the plurality of pixels 02 are arranged along a row direction and a column direction and the array substrate includes a plurality of rows and columns of pixels. Optionally, in conjunction with FIG. 1 and FIG. 3, the first direction X1 and the column direction are the same direction, and the second direction X2 and the row direction are the same direction.

The plurality of shift register units 031 and the plurality of gate leads G2 are coupled to each other in one-to-one correspondence, the plurality of gate leads G2 and the plurality of gate lines G1 are connected to each other in one-to-one correspondence, the connection portions are disposed within the plurality of cutouts D in one-to-one correspondence, and the plurality of gate lines G1 and the plurality of rows of pixels 02 are coupled to each other in one-to-one correspondence. That is, each of the shift register units 031 is coupled to one different gate lead G2. Each of the gate leads G2 is coupled to one different gate line G1. Each of the gate lines G1 is coupled to one different row of pixels 02. Each of the shift register units 031 is configured to supply the gate drive signal to a row of pixels 02 via one gate lead G2 and one gate line G1, such that a progressive scanning is achieved.

In some embodiments, each of the shift register units 031 is coupled to two or more rows of pixels 02 by the gate leads G2 and the gate lines G1.

In some embodiments, referring to FIG. 3, each of the gate leads G2, each of the cutouts D, and each of the gate lines G1, which are in one-to-one correspondence, are successively arranged along the same horizontal line in the second direction X2. That is, for each of the gate leads G2, the gate lead G2, the cutout D corresponding to the gate lead G2, and the gate line G1 corresponding to the gate lead G2 are disposed on the same horizontal line extending along the second direction X2. In this way, the layout is further ensured to be more regular, and thus the wiring is simplified.

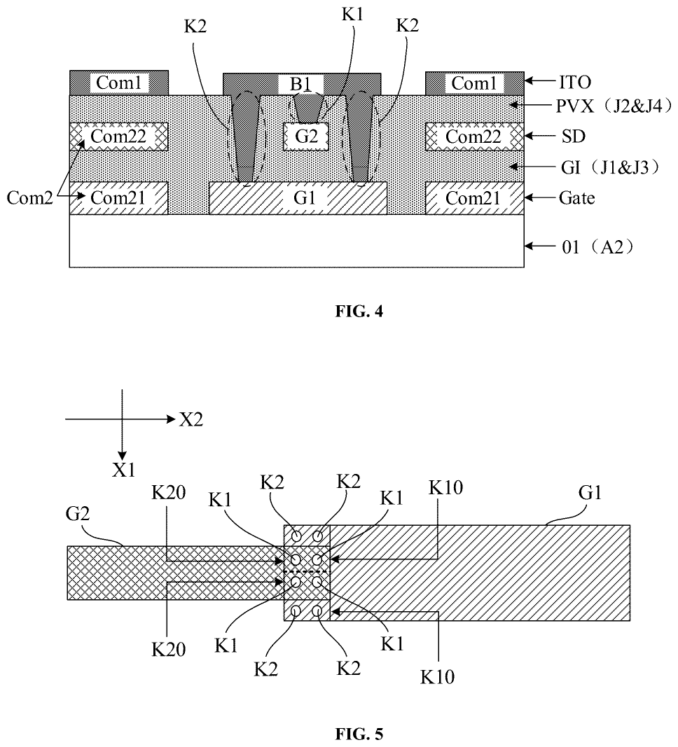

In some embodiments, in conjunction with FIG. 2 and a sectional diagram of another array substrate in an a1-a2 direction as illustrated in FIG. 4, the array substrate according to some embodiments of the present disclosure further includes: a first insulator layer J1 disposed between the gate line G1 and the gate lead G2, a second insulator layer J2 disposed on a side, distal from the substrate 01, of the gate lead G2, a first connection portion B1 disposed on a side, distal from the substrate 01, of the second insulator layer J2, a plurality of first vias K1 running through the second insulator layer J2, and a plurality of second vias K2 running through the second insulator layer J2 and the first insulator layer J1. Accordingly, the plurality of first vias K1 expose the gate lead G2 and the plurality of second vias K2 expose the gate line G1.

It should be noted that FIG. 4 only schematically illustrates two second vias K2 and one first vias K1.

Referring to FIG. 4, an orthographic projection of the gate lead G2 on the substrate 01 is within an orthographic projection of the gate line G1 on the substrate 01, and orthographic projections of the plurality of first vias K1 on the substrate 01 are not overlapped with orthographic projections of the plurality of second vias K2 on the substrate 01. The first connection portion B1 is lapped to the gate lead G2 through the plurality of first vias K1, and is lapped to the gate line G1 through the plurality of second vias K2, such that the gate line G1 is connected to the gate lead G2. That is, the gate line G1 and the gate lead G2 are indirectly connected to each other by the first connection portion B1, and the first via K1 and the second via K2 are considered as connection holes for the gate line G1 and the gate lead G2. In this case, the plurality of first vias K1 and the plurality of second vias K2 are connected in parallel. By providing the plurality of first vias K1 and the plurality of second vias K2 that are connected in parallel, resistances of the connection holes are reduced, and the reliability of the connection is improved.

In some embodiments, the array substrate has only vias running through the first insulator layer J1 and exposing the gate line G1. On this basis, the gate lead G2 is directly lapped to the gate line through the via running through the first insulator layer J1 and exposing the gate line G1.

In some embodiments, referring to a partial schematic diagram of an array substrate as illustrated in FIG. 5, the number of the plurality of first vias K1 is the same as the number of the plurality of second vias K2, such that the resistances of the plurality of first vias K1 and the resistances of the plurality of second vias K2 are ensured to be the same, and thus the connection is further ensured to be reliable and stable.

In some embodiments, the number of the plurality of first vias K1 and the number of the plurality of second vias K2 are both greater than or equal to four and less than or equal to eight.

In some embodiments, referring to FIG. 5, the plurality of first vias K1 are organized into a plurality of first via groups K10 successively arranged along the first direction X1. Each of the first via groups K10 includes a plurality of first vias K1 successively arranged along the second direction X2, and the number of first vias K1 included in each first via group K10 is less than or equal to the number of the plurality of first via groups K10. The plurality of second vias K2 are organized into a plurality of second via groups K20 successively arranged along the first direction X1. Each of the second via groups K20 includes a plurality of second vias K2 successively arranged along the second direction X2, and the number of second vias K2 included in each second via group K20 is less than or equal to the number of the plurality of second via groups K20.

In this way, a length of the connection portion of the gate lead G2 and the gate line G1 in the first direction X1 is greater than or equal to a length of that in the second direction X2. That is, a length direction of the connection portion of the gate lead G2 and the gate line G1 is parallel to the first direction X1. In this way, the space in the wiring region A2 is better utilized, such that the area of the substrate 01 occupied by the non-display region is small enough to lay a good foundation for the narrow frame design.

For example, referring to FIG. 5, the number of the plurality of first vias K1 and the number of the plurality of second vias K2 illustrated therein are both four. The plurality of first vias K1 are organized into two first via groups K10 successively arranged along the first direction X1, and each of the two first via groups K10 includes two first vias K1 successively arranged along the second direction X2. The plurality of second vias K2 are organized into two second via groups K20 successively arranged along the first direction X1. Each of the two second via groups K20 includes two second vias K2 successively arranged along the second direction X2. In this case, referring to FIG. 5, the gate line G1 and the gate lead G2 are considered to be connected to each other through four pairs of vias, and thus the four pairs of vias are connected in parallel.

In some embodiments, referring to FIG. 4, the first connection portion B1 and the common electrode line Com1 are disposed in the same layer.

It should be noted that the term “disposed in the same layer” refers to a layer structure formed by forming a film layer for forming a particular pattern using the same film forming process and then patterning the film layer by a one-time patterning process using the same mask. Depending on the specific pattern, the one-time patterning process includes multiple exposure, developing, or etching processes, and the specific pattern in the formed layer structure is continuous or discontinuous. That is, a plurality of components, parts, structures, and/or sections disposed in the “same layer” are made of the same material and formed by the same patterning process. In this way, the manufacturing process is simplified and the manufacturing cost is saved, and the manufacturing efficiency is accelerated.

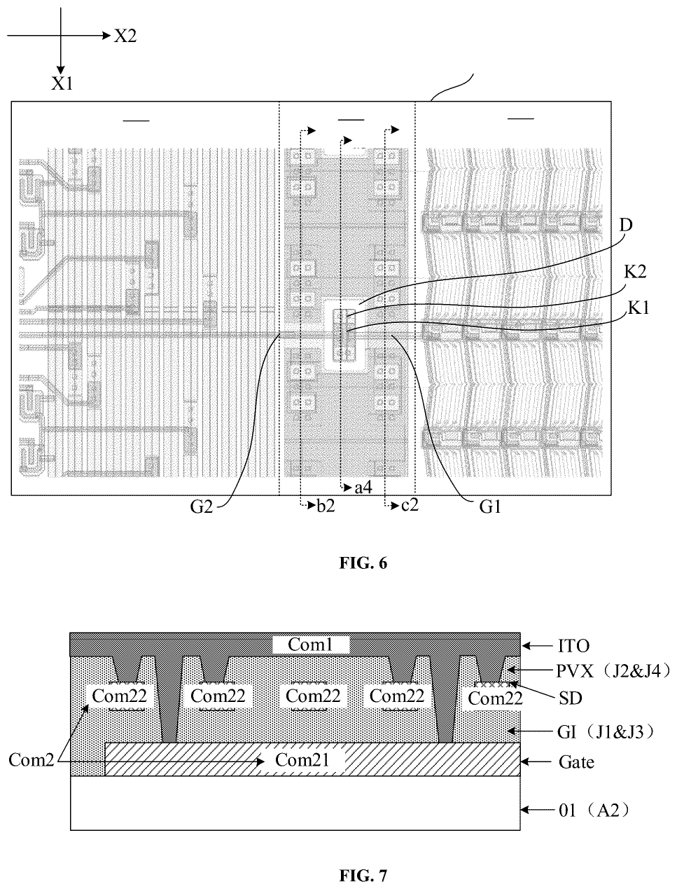

Based on FIG. 1 to FIG. 5, FIG. 6 illustrates a structural layout of an array substrate. Referring to FIG. 6, the common electrode line Com1 disposed in the wiring region includes the cutout D, and the gate lead G2 disposed in the circuit region A3 and the wiring region A2 and the gate line G1 disposed in the wiring region A2 and the display region A1 are connected to each other within the cutout D through the connection hole. FIG. 4 is a sectional diagram of the structural layout illustrated in FIG. 6 in an a3-a4 direction.

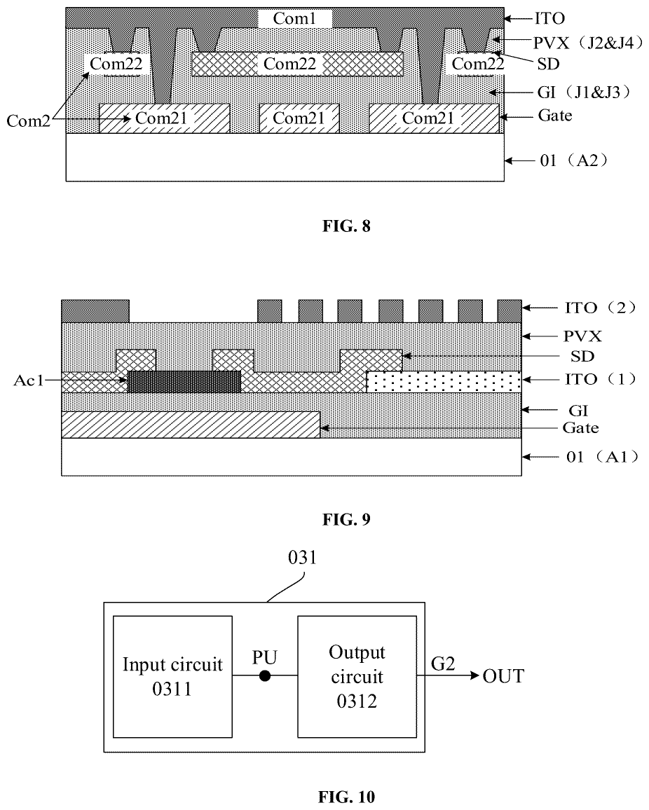

FIG. 7 illustrates a sectional diagram of the structural layout diagram in FIG. 6 in a b1-b2 direction, and FIG. 8 illustrates a sectional diagram of the structural layout diagram in FIG. 6 in a c1-c2 direction. In conjunction with FIG. 4, FIG. 7, and FIG. 8, the array substrate according to some embodiments of the present disclosure further includes: a common electrode lead Com2 disposed in the wiring region A2.

The common electrode lead Com2 includes: a first electrode line Com21 and a second electrode line Com22 that are disposed between the substrate 01 and the common electrode line Com1 and successively stacked along the direction away from the substrate 01. On this basis, the array substrate further includes: a third insulator layer J3 disposed between the first electrode line Com21 and the second electrode line Com22, and a fourth insulator layer J4 disposed between the second electrode line Com22 and the common electrode line Com1

The common electrode line Com1 is lapped to the second electrode line Com22 through a via (not illustrated in the figures) running through the fourth insulator layer J4, and is lapped to the first electrode line Com21 through a via (not illustrated in the figures) running through the third insulator layer J3 and the fourth insulator layer J4, such that the common electrode line Com 1 receives common signals supplied by the first electrode line Com21 and the second electrode line Com22. That is, the common signal is originally supplied by an external integrated circuit (IC) to the common electrode lead Com2, and is conducted by the common electrode lead Com2 to the common electrode line Com1 disposed in the wiring region A2, and is finally conducted by the common electrode line Com1 to the common electrode disposed in the display region A1.

In some embodiments, referring to FIG. 7 and FIG. 8, the first electrode line Com21 and the second electrode line Com22 according to some embodiments of the present disclosure both include a plurality of electrode blocks spaced apart. That is, as illustrated in FIG. 7 and FIG. 8, the first electrode line Com21 and the second electrode line Com22 that are arranged on a side of the substrate 01 are both not provided as a whole, but include a plurality of spaced portions, and the common electrode line Com1 is lapped to each of the spaced portions. This design is considered as a gridding design for the common electrode lead Com2.

By the gridding design for the common electrode lead Com2, large solid metals arranged on the substrate 01 are reduced, such that other film layers (e.g., active layers) are prevented from being burned during the preparation process due to large heating areas of the large metal, and thus the product yield is better. Due to the gridding design for the common electrode lead Com2, a certain space is wasted, which is contrary to the requirement of the narrow frame design if combined with the layout method in the related art. In the embodiments of the present disclosure, the problem of wasting space caused by the gridding design for the common electrode lead Com2 is avoided because the layout of the connection portion and the common electrode lead Com1 is adjusted.

Optionally, FIG. 9 illustrates a sectional diagram of a pixel within a display region. As illustrated in FIG. 9, the pixel 02 according to some embodiments of the present disclosure includes: a gate metal layer Gate, a gate insulator layer GI, a source-drain metal layer SD, a passivation layer PVX, and an electrode layer ITO that are successively stacked along the direction away from the substrate 01.

In conjunction with FIG. 4, FIG. 7 and FIG. 8, the first electrode line Com21 and the gate line G1 are disposed in the same layer, and are both disposed in the same layer as the gate metal layer Gate. The second electrode line Com22 and the gate lead G2 are disposed in the same layer, and are both disposed in the same layer as the source-drain metal layer SD. The first insulator layer J1 and the third insulator layer J3 are disposed in the same layer, and are both disposed in the same layer as the gate insulator layer GI. The second insulator layer J2 and the fourth insulator layer J4, and are both disposed in the same layer as the passivation layer PVX. The common electrode line Com1 and the electrode layer ITO are disposed in the same layer. In this way, the manufacturing process is further simplified and the manufacturing cost is further saved, and the manufacturing efficiency is further accelerated.

That is, in both the wiring region A2 and the circuit region A3, the array substrate includes the gate metal layer Gate, the gate insulator layer GI, the source-drain metal layer SD, the passivation layer PVX, and the electrode layer ITO that are successively stacked along the direction away from the substrate 01. In one aspect, the gate lead G2 is formed using the source-drain metal layer SD, and the gate line G1 is formed using the gate metal layer Gate. Then, the electrode layer ITO is lapped to the source-drain metal layer SD and the gate metal layer Gate, such that a conduction between the source-drain metal layer SD and the gate metal layer Gate is achieved. That is, the gate lead G2 is reliably coupled to the gate line G1. In another aspect, the common electrode lead Com2 is formed using the source-drain metal layer SD and the gate metal layer Gate, and the common electrode line Com1 is formed using the electrode layer ITO. Then the common signal is conducted by the IC over the source-drain metal layer SD and the gate metal layer Gate to the electrode layer ITO disposed in the wiring region A2, and is finally conducted by the electrode layer ITO disposed in the wiring region A2 to the electrode layer ITO in the pixel 02 disposed in the display region A1.

In some embodiments, referring to FIG. 9, the pixel 02 according to some embodiments of the present disclosure further includes an active layer Ac1 disposed between the gate insulator layer GI and the source-drain metal layer SD, and another electrode layer ITO. To distinguish the electrode layer ITO from the electrode layer ITO described above, in FIG. 9, the electrode layer ITO disposed in the same layer as the common electrode line Com1 is identified as “ITO (2)” and the other electrode layer ITO is identified as “ITO (1).”

One of the electrode layer ITO (1) and the electrode layer ITO (2) is a pixel electrode and the other is a common electrode. The description is given using a scenario where the electrode layer ITO (2) is the common electrode and the electrode layer ITO (1) is the pixel electrode as an example. The active layer Ac1 is lapped to the source-drain metal layer SD, and an orthographic projection of the active layer Ac1 on the substrate 01 is not overlapped with an orthographic projection of the electrode layer ITO (2) on the substrate 01.

The structure illustrated in FIG. 9 is prepared using a 6 mask process. The via running through the passivation layer PVX and the gate insulator layer GI, and the via running through the passivation layer PVX are acquired by a one-time mask process. In this way, the manufacturing process is simplified, the manufacturing cost is saved, and the manufacturing efficiency is accelerated. The 6 mask process refers to a preparation successively in six steps using the mask.

The six steps are as follows. (1) The gate metal layer Gate is formed on the substrate 01 using the mask. Afterward, the gate insulator layer GI is formed on a side, distal from the substrate 01, of the gate metal layer Gate using the deposition process. (2) The active layer Ac1 is formed on a side, distal from the substrate 01, of the gate insulator layer GI using the mask. (3) The electrode layer ITO (1) is formed on a side distal from the substrate 01, of the gate insulator layer GI using the mask. (4) The source-drain metal layer SD is formed on side, distal from the substrate 01, of the active layer Ac1 using the mask. (5) The passivation layer PVX is formed on a side, distal from the substrate 01, of the source-drain metal layer SD using the mask. (6) The electrode layer ITO (2) is formed on a side, distal from the substrate 01, of the passivation layer PVX using the mask. The TFT in the pixel 02 prepared by this process is referred to as a bottom-gate TFT. In some embodiments, the TFT is a top-gate TFT, and in this case, the gate metal layer Gate is disposed on the side, distal from the substrate 01, of the active layer Ac1.

In some embodiments, the gate metal layer Gate is made of metallic materials or alloy materials, such as molybdenum (Mo), aluminum (Al), and titanium (Ti). The gate insulator layer GI and the passivation layer PVX are made of inorganic materials, such as silicon oxide (SiOx) or silicon nitride (SiNx). The active layer Ac1 is made of polysilicon materials. The source-drain metal layer SD is made of metallic materials or alloy materials, such as molybdenum (Mo), aluminum (Al), and titanium (Ti). The electrode layers ITO (1) and ITO (2) are made of indium tin oxide (ITO), which is a transparent material, and thus a good transmittance is achieved. In some embodiments, the electrode layers ITO (1) and ITO (2) are made of other types of transparent materials, such as indium zinc oxide or zinc oxide. The substrate 01 is a single-layer structure or a double-layer structure, and is a rigid substrate made of glass or a flexible substrate made of polyimide flexible materials.

Referring to FIG. 1 and FIG. 3, in some embodiments of the present disclosure, the array substrate further includes: a plurality of data lines disposed in the display region A1. The plurality of data lines are coupled to the plurality of columns of pixels 02 in one-to-one correspondence, such that the plurality of data line supply data signals to the pixels 02. The data line and the source-drain metal layer SD are disposed in the same layer.

FIG. 10 is a schematic structural diagram of a shift register unit according to some embodiments of the present disclosure. As illustrated in FIG. 10, each of the shift register units 031 in the gate drive circuit 03 includes an input circuit 0311 and an output circuit 0312.

The input circuit 0311 is coupled to a plurality of drive signal lines (not illustrated in FIG. 10) and a pull-up node PU, and is configured to charge the pull-up node PU in response to drive signals supplied by the plurality of drive signal lines.

The output circuit 0312 is coupled to the pull-up node PU and the gate lead G2, and is configured to transmit the gate drive signal to the gate lead G2 based on a potential of the pull-up node PU. On this basis, the gate lead G2 according to some embodiments of the present disclosure is actually an output terminal of the shift register unit 031.

In some embodiments, the drive signal line includes: a clock signal line, a power supply line, and/or a reset signal line. Moreover, the output circuit 0312 is generally coupled to the clock signal line and transmits a clock signal from the clock signal line to the gate line G2 based on the potential of the pull-up node PU. In this case, the clock signal is determined as the gate drive signal.

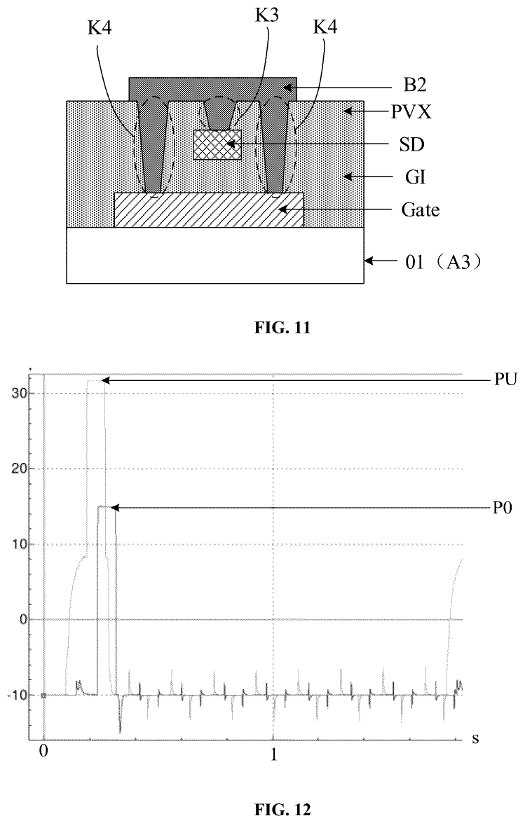

FIG. 11 is a schematic sectional diagram of another shift register unit according to some embodiments of the present disclosure. In conjunction with FIG. 9 and FIG. 11, the input circuit 0311, the output circuit 0312, and the plurality of drive signal lines according to some embodiments of the present discloser also include: a gate metal layer Gate, a gate insulator layer GI, a source-drain metal layer SD, and a passivation layer PVX that are successively stacked along the direction away from the substrate. The gate metal layer Gate, the gate insulator layer GI, the source-drain metal layer SD, and the passivation layer PVX herein are respectively disposed in the same layer as the gate metal layer Gate, the gate insulator layer GI, the source-drain metal layer SD, and the passivation layer PVX included in the pixel 02 in one-to-one correspondence.

Referring to FIG. 11, in some embodiments, the array substrate further includes a second connection portion B2 disposed on a side, distal from the substrate 01, of the passivation layer PVX.

The second connection portion B2 is lapped to the source-drain metal layer SD through a plurality of third vias K3 running through the passivation layer PVX, and is lapped to the gate metal layer Gate through a plurality of fourth vias K4 running through the passivation layer PVX and the gate insulator layer GI, such that the input circuit 0311 and the drive signal line are coupled at a coupling node PO, and the input circuit 0311 and the output circuit 0312 are coupled at the pull-up node PU.

That is, the second connection portion B2 disposed on a side, distal from the substrate 01, of the source-drain metal layer SD is lapped to the source-drain metal layer SD and the gate metal layer Gate that are disposed in different layers, such that a reliable coupling between the source-drain metal layer SD and the gate metal layer Gate that are disposed in different layers of the shift register unit 031 is achieved. The third via K3 and the fourth via K4 are connection holes. In this case, the plurality of third vias K3 are considered to be connected in parallel to the plurality of fourth vias K4. By arranging the plurality of third vias K3 and the plurality of fourth vias K4 that are connected in parallel, the resistances of the connection hole are reduced, and the reliability of the connection is improved.

In some embodiments, the array substrate includes only vias running through the gate insulator layer GI and exposing the gate metal layer Gate. On this basis, the source-drain metal layer SD is directly lapped to the gate metal layer Gate through the via running through the gate insulator layer GI and exposing the gate metal layer Gate.

In some embodiments, similar to the first connection portion B1, the second connection portion B2 herein is also disposed in the same layer as the common electrode line Com1. Because the common electrode line Com1 and the electrode layer ITO are disposed in the same layer, the second connection portion B2 and the electrode layer ITO are disposed in the same layer. Furthermore, an orthographic projection of the source-drain metal layer SD on the substrate 01 is also within an orthographic projection of the gate metal layer Gate on the substrate 01, and orthographic projections of the plurality of third vias K3 on the substrate 01 are not overlapped with and orthographic projections of the plurality of fourth vias K4 on the substrate 01.

The number of third vias K3 that are run through for coupling at the pull-up node PU is greater than the number of third vias K3 that are run through for coupling at the coupling node P0. The number of fourth vias K4 that are run through for coupling at the pull-up node PU is greater than the number of third vias K4 that are run through for coupling at the coupling node P0. That is, the number of vias formed for coupling between portions at the pull-up node PU is greater than the number of vias formed for coupling between portions at the coupling node P0.

A voltage at the pull-up node PU is generally much greater than voltages at other coupling nodes P0 other than the pull-up node PU when the gate drive signal is output. For example, referring to the diagram of analog voltages at nodes illustrated in FIG. 12, the voltage at the pull-up node PU generally reaches up to 30 V, while the voltages at the other coupling nodes P0 generally reach up to only 15 V. The horizontal coordinate in FIG. 12 refers to the time in seconds(s), and the vertical coordinate refers to the voltage in V. In addition, the higher the voltage at a position, the higher the possibility of electrochemical corrosion when the position is exposed to water vapor. Therefore, by arranging a large number of vias for coupling between portions at the pull-up node PU, the reliability of the connection is improved, and the probability of the electrochemical corrosion is reduced. Because the voltages at the other coupling nodes P0 are small, there is no need to arrange a larger number of vias for coupling.

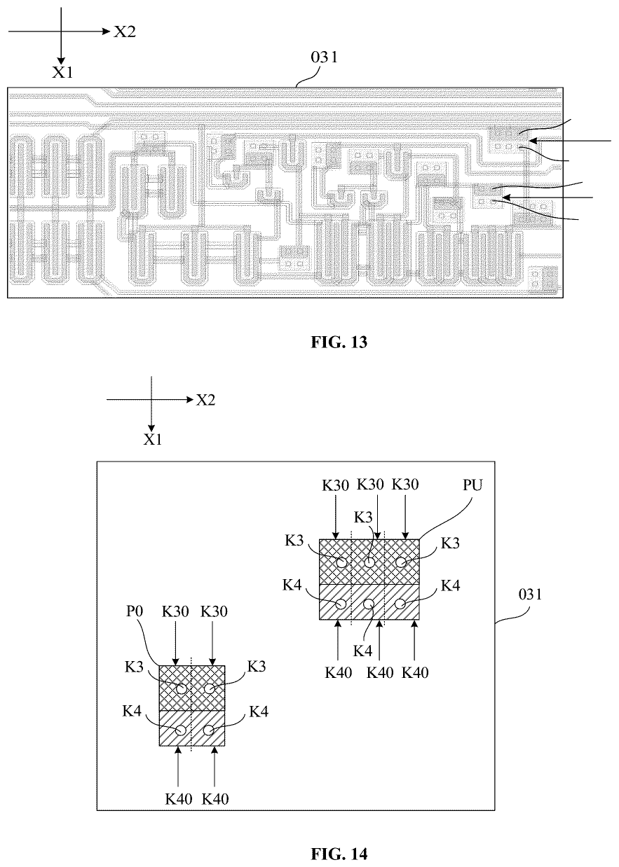

FIG. 13 is a structural layout of a shift register unit according to some embodiments of the present disclosure, and FIG. 14 is a partial structural layout of the structure illustrated in FIG. 13 at the pull-up node PU and one of the coupling nodes P0. Referring to FIG. 13 and FIG. 14, the number of third vias K3 that are run through for coupling at the pull-up node PU is equal to the number of fourth vias K4 that are run through for coupling at the pull-up node PU. The number of third vias K3 that are run through for coupling at the coupling node P0 is equal to the number of third vias K4 that are run through for coupling at the coupling node P0. In this way, for any of the nodes, the resistance at the plurality of third vias K3 is ensured to be equal to the resistance at the plurality of fourth vias K4, such that a reliable connection is ensured.

In some embodiments, the number of third vias K3 and the number of fourth vias K4 that are run through for coupling at the pull-up node PU are both greater than or equal to 3 and less than or equal to 6. The number of third vias K3 and the number of fourth vias K4 that are run through for coupling at the coupling node P0 are both less than or equal to 2.

In some embodiments, referring to FIG. 14, the plurality of third vias K3 that are run through for coupling at the pull-up node PU and the plurality of third vias K3 that are run through for coupling at the coupling node P0 are organized into a plurality of third via groups K30 successively arranged along the second direction X2, and each of the third via groups K30 includes a third via K3. The plurality of fourth vias K4 that are run through for coupling at the pull-up node PU and the plurality of fourth vias K4 that are run through for coupling at the coupling node P0 are organized into a plurality of fourth via groups K40, and each of the fourth via groups K40 includes a fourth via K4. The fourth via groups K40 and the third via groups K30 are successively arranged along the first direction X1.

That is, in some embodiments of the present disclosure, either at the pull-up node PU or any other node of the coupling nodes P0, the plurality of third vias K3 that are run through for the connection are successively arranged along the second direction X2, the plurality of fourth vias K4 that are run through for the connection are successively arranged along the second direction X2, and the third vias K3 and the fourth vias K4 are successively arranged along the first direction X1. In this way, a length of the connection portion at the node in the first direction X1 is less than a length of that in the second direction X2. That is, a length direction of the connection portion at the node is parallel to the second direction X2. Therefore, the space in the circuit region A3 is better utilized, such that the non-display region occupies a small enough area of the substrate 01, which lays a good foundation for the narrow frame design. In some embodiments, assuming that the number of third vias K3 and the number of fourth vias K4 that are run through at a node are both 1, the third via K3 and fourth via K4 are arranged along the first direction X1.

For example, referring to FIG. 13 and FIG. 14, the number of the plurality of third vias K3 and the number of the plurality of fourth vias K4 that are run through for coupling at the pull-up node PU are both three. Accordingly, the plurality of third vias K3 that are run through for coupling at the pull-up node PU are organized into three third via groups K30 successively arranged along the second direction X2; and the plurality of fourth vias K4 that are run through for coupling at the pull-up node PU are organized into three fourth via groups K40 successively arranged along the second direction X2. In this case, referring to FIG. 14, at the pull-up node PU, the source-drain metal layer SD and the gate metal layer Gate are connected through three pairs of vias, which forms a parallel connection between the three pairs of vias. Moreover, the number of the plurality of third vias K3 and the number of the plurality of fourth vias K4 that are run through for coupling at the coupling node PO are both two. Accordingly, the plurality of third vias K3 that are run through for coupling at the coupling node P0 are organized into two third via groups K30 successively arranged along the second direction X2; and the plurality of fourth vias K4 that are run through for coupling at the coupling node P0 are organized into two fourth via groups K40 successively arranged along the second direction X2. In this case, referring to FIG. 14, at other coupling nodes P0, the source-drain metal layer SD and the gate metal layer Gate are connected through two pairs of vias, which forms a parallel connection between the two pairs of vias. Based on this, referring to FIG. 6, within the circuit region A3, vertical holes are formed at each vertical line extending along the first direction X1, which improves the reliability and saves frames.

In summary, some embodiments of the present disclosure provide an array substrate. The array substrate includes the substrate including the display region, the wiring region, and the circuit region that are successively adjacent, the pixel disposed in the display region, the common electrode line disposed in the wiring region and including the cutout, the gate lead disposed in the wiring region and the circuit region, the gate line disposed in the wiring region and the display region, and the gate drive circuit disposed in the circuit region. In particular, the gate lead and the gate line are disposed in different layers and connected to each other; the gate drive circuit is coupled to the pixel by the mutually connected gate lead and the gate line and supplies the gate drive signal to the pixel; and the common electrode line is coupled to the pixel and supplies the common signal to the pixel. Because the connection portion of the gate lead and the gate line is within the cutout of the common electrode line, that is, within the wiring region, the space is fully utilized, such that the area of the substrate occupied by other portions other than the display region is small, which facilitates the narrow frame design of the array substrate.

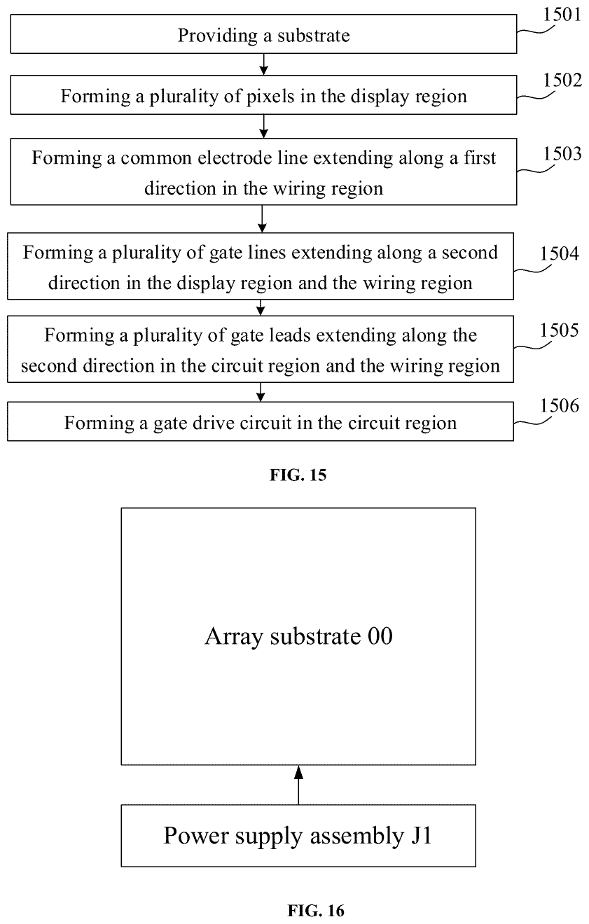

FIG. 15 is a flowchart of a method for preparing an array substrate according to some embodiments of the present disclosure, which is employed to prepare an array substrate as described above. As illustrated in FIG. 15, the method includes the following steps.

In step 1501, a substrate is provided.

Referring to FIG. 1, the provided substrate 01 includes a display region, A1, a wiring region A2, and a circuit region A3, wherein the wiring region A2 and the circuit region A3 are disposed on at least one side of the display region A1 and successively arranged in a direction away from the display region A1.

In step 1502, a plurality of pixels are formed in the display region.

In step 1503, a common electrode line extending along a first direction is formed in the wiring region.

Referring to FIG. 1, the formed common electrode line Com1 includes a plurality of cutouts D spaced apart. The common electrode line Com1 is coupled to the plurality of pixels 02 and is configured to supply common signals to the plurality of pixels 02.

In step 1504, a plurality of gate lines extending along a second direction are formed in the display region and the wiring region.

Referring to FIG. 1, the second direction X2 is intersected with the first direction X1. For example, the second direction X2 and the first direction X1 are perpendicular to each other as illustrated in FIG. 1.

In step 1505, a plurality of gate leads extending along the second direction are formed in the circuit region and the wiring region.

Referring to FIG. 2, the formed plurality of gate leads G2 are disposed on a side, distal from the substrate 01, of the gate line G1 and are disposed on a side, proximal to the substrate 01, of the common electrode line Com1.

In step 1506, a gate drive circuit is formed in the circuit region.

Referring to FIG. 2, the formed gate drive circuit 03 is coupled to a plurality of gate leads G2, the plurality of gate leads G2 are further coupled to the plurality of gate lines G1, and the plurality of gate lines G1 are further coupled to the plurality of pixels 02. In this way, the gate drive circuit 03 is reliably connected to the pixels 02. On this basis, the gate drive circuit 03 is configured to supply gate drive signals to the plurality of pixels 02 by the plurality of gate leads G2 and the plurality of gate lines G1. In addition, in the embodiments of the present disclosure, a connection portion of the gate lead G2 and the gate line G1 is disposed within the cutout D. In this way, a space on the substrate 01 is fully utilized, which facilitates a narrow frame design of the array substrate.

It may be understood that, the above preparation method according to the embodiments of the present disclosure should have the same features and advantages as the array substrate according to the embodiments of the present disclosure, and thus the features and advantages of the above preparation method according to the embodiments of the present disclosure may refer to the features and advantages of the array substrate as described above, which is not repeated herein.

In addition, although the individual steps of the method are described in the accompanying drawings in a particular order, it is not required or implied that these steps must be performed in above particular order or that all of the steps illustrated must be performed to achieve the desired results. Additional or alternatively, certain steps may be omitted, multiple steps may be combined into a single step to perform, and/or, a single step may be divided into multiple steps to perform. In addition, some of the above steps may be performed in parallel or successively, which are not limited to the specific operation order described above. The specific method of each step may refer to the embodiments of the device side described above and is not repeated herein.

FIG. 16 is a schematic structural diagram of a display device according to some embodiments of the present disclosure. As illustrated in FIG. 16, the display device includes: a power supply assembly J1, and an array substrate 00 as illustrated in any of the accompanying drawings. The power supply assembly JI is coupled to the array substrate 00 and is configured to supply power to the array substrate 00.

In some embodiments, the display device includes: an in-vehicle display device, an LCD device, a smartphone, a tablet computer, a television, a display, and any product or component having a display function.

It should be noted that the terms used in the detailed description of the present disclosure are merely for interpreting, instead of limiting, the embodiments of the present disclosure. Unless otherwise defined, technical or scientific terms used in the embodiments of the present disclosure shall have ordinary meanings understandable by persons of ordinary skill in the art to which the disclosure belongs.

For example, the terms “first,” “second,” “third,” and the like used in the embodiments of the present disclosure are not intended to indicate any order, quantity, or importance, but are merely used to distinguish the different components.

Similarly, the terms “one” and the like are not intended to indicate any quantitative limit, but are merely used to indicate the presence of at least one.

The terms “comprise,” “include,” and derivatives or variations thereof are used to indicate that the element or object preceding the terms covers the element or object following the terms and its equivalents, and shall not be understood as excluding other elements or objects.

The terms “on,” “under,” “left,” and “right” are only used to indicate the relative positional relationship. When the absolute position of the described object changes, the relative positional relationship may change accordingly.

The term “and/or” mentioned in the embodiments of the present disclosure indicates three relationships between contextual objects. For example, A and/or B may mean that A exists alone, A and B exist at the same time, and B exists alone. The symbol “/” generally denotes an “OR” relationship between contextual objects.

Described above are merely exemplary embodiments of the present disclosure, and are not intended to limit the present disclosure. Therefore, any modifications, equivalent substitutions, improvements, and the like made within the spirit and principles of the present disclosure shall be included in the protection scope of the present disclosure.

1. An array substrate, comprising:
a substrate, comprising a display region, a wiring region, and a circuit region, wherein the wiring region and the circuit region are disposed on at least one side of the display region and successively arranged along a direction away from the display region;
a plurality of pixels, disposed in the display region;
a common electrode line, extending along a first direction and disposed in the wiring region, wherein the common electrode line comprises a plurality of cutouts spaced apart and is coupled to the plurality of pixels;
a plurality of gate lines, extending along a second direction and disposed in the display region and the wiring region, wherein the first direction is intersected with the second direction;
a plurality of gate leads, extending along the second direction and disposed in the circuit region and the wiring region, wherein the plurality of gate leads are disposed on a side, distal from the substrate, of the gate line and a side, proximal to the substrate, of the common electrode line; and
a gate drive circuit, disposed in the circuit region and coupled to the plurality of gate leads, wherein the plurality of gate leads are connected to the plurality of gate lines by a connection portion disposed within the cutout, and the plurality of gate lines are coupled to the plurality of pixels.

2. The array substrate according to claim 1, wherein an edge of each of the cutouts is spaced from an edge of the common electrode line, and the edges of the cutouts are equally spaced from any edge, in the second direction, of the common electrode line; and
the plurality of cutouts are spaced apart along the first direction.

3. The array substrate according to claim 1, wherein the gate drive circuit comprises: a plurality of shift register units that are successively arranged and cascaded along the first direction, and the plurality of pixels are arranged in arrays;
wherein the plurality of shift register units are coupled to the plurality of gate leads in one-to-one correspondence, the plurality of gate leads are connected to the plurality of gate lines in one-to-one correspondence by connection portions disposed within the plurality of cutouts in one-to-one correspondence, and the plurality of gate lines are coupled to a plurality of rows of the pixels in one-to-one correspondence.

4. The array substrate according to claim 3, wherein each of the gate leads, each of the cutouts, and each of the gate lines, which are in one-to-one correspondence, are successively arranged in the second direction along a same horizontal line.

5. The array substrate according to claim 1, further comprising:
a first insulator layer disposed between the gate line and the gate lead;
a second insulator layer disposed on a side, distal from the substrate, of the gate lead;
a first connection portion disposed on a side, distal from the substrate, of the second insulator layer; and
a plurality of first vias running through the second insulator layer, and a plurality of second vias running through the second insulator layer and the first insulator layer;
wherein an orthographic projection of the gate lead on the substrate is within an orthographic projection of the gate line on the substrate, and orthographic projections of the plurality of first vias on the substrate are not overlapped with orthographic projections of the plurality of second vias on the substrate; and
the first connection portion is lapped to the gate lead through the plurality of first vias and lapped to the gate line through the plurality of second vias, such that the gate line is connected to the gate lead.

6. The array substrate according to claim 5, wherein there is at least one of:
a number of the plurality of first vias is equal to a number of the plurality of second vias; or
a number of the plurality of first vias and a number of the plurality of second vias are both greater than or equal to four and less than or equal to eight.

7. (canceled)

8. The array substrate according to claim 6, wherein the plurality of first vias are organized into a plurality of first via groups successively arranged along the first direction, wherein each of the first via groups comprises a plurality of the first vias successively arranged along the second direction, and a number of the first vias in each of the first via groups is less than or equal to a number of the plurality of first via groups; and
the plurality of second vias are organized into a plurality of second via groups successively arranged along the first direction, wherein each of the second via groups comprises a plurality of the second vias successively arranged along the second direction, and a number of the second vias in each of the second via groups is less than or equal to a number of the plurality of second via groups.

9. The array substrate according to claim 8, wherein the number of the plurality of first vias and the number of the plurality of second vias are both four;
the plurality of first vias are organized into two of the first via groups successively arranged along the first direction, and each of the first via groups comprises two of the first vias successively arranged along the second direction; and
the plurality of second vias are organized into two of the second via groups successively arranged along the first direction, and each of the second via groups comprises two of the second vias successively arranged along the second direction.

10. The array substrate according to claim 5, wherein the first connection portion and the common electrode line are disposed in a same layer.

11. The array substrate according to claim 5, wherein
the array substrate further comprises: a common electrode lead disposed in the wiring region, wherein the common electrode lead comprises: a first electrode line and a second electrode line that are disposed between the substrate and the common electrode line and successively stacked along a direction away from the substrate; and
the array substrate further comprises: a third insulator layer disposed between the first electrode line and the second electrode line, and a fourth insulator layer disposed between the second electrode line and the common electrode line;
wherein the common electrode line is lapped to the second electrode line through a via running through the fourth insulator layer, and is lapped to the first electrode line through a via running through the third insulator layer and the fourth insulator layer.

12. The array substrate according to claim 11, wherein the first electrode line comprises a plurality of first electrode blocks spaced apart, and the second electrode line comprises a plurality of second electrode blocks spaced apart.

13. The array substrate according to claim 11, wherein the pixel comprises: a gate metal layer, a gate insulator layer, a source-drain metal layer, a passivation layer, and an electrode layer that are successively stacked along the direction away from the substrate; wherein
the first electrode line and the gate line are disposed in a same layer, and are both disposed in a same layer as the gate metal layer;
the second electrode line and the gate lead are disposed in a same layer, and are both disposed in a same layer as the source-drain metal layer;
the first insulator layer and the third insulator layer are disposed in a same layer, and are both disposed in a same layer as the gate insulator layer;
the second insulator layer and the fourth insulator layer are disposed in a same layer, and are both disposed in a same layer as the passivation layer; and
the common electrode line and the electrode layer are disposed in a same layer.

14. The array substrate according to claim 1, wherein each of the shift register units in the gate drive circuit comprises an input circuit and an output circuit; wherein
the input circuit is coupled to a plurality of drive signal lines and a pull-up node, and is configured to charge the pull-up node in response to drive signals from the plurality of drive signal lines; and
the output circuit is coupled to the pull-up node and the gate lead, and is configured to transmit a gate drive signal to the gate lead based on a potential of the pull-up node.

15. The array substrate according to claim 14, wherein the input circuit, the output circuit, and the plurality of drive signal lines comprise a gate metal layer, a gate insulator layer, a source-drain metal layer, and a passivation layer that are successively stacked along the direction away from the substrate; and
the array substrate further comprises a second connection portion disposed on a side, distal from the substrate, of the passivation layer, wherein the second connection portion is lapped to the source-drain metal layer through a plurality of third vias running through the passivation layer, and is lapped to the gate metal layer through a plurality of fourth vias running through the passivation layer and the gate insulator layer, such that the input circuit is coupled to the drive signal line at a coupling node, and the input circuit is coupled to the output circuit at the pull-up node;
wherein an orthographic projection of the source-drain metal layer on the substrate is within an orthographic projection of the gate metal layer on the substrate, and orthographic projections of the plurality of third vias on the substrate are not overlapped with orthographic projections of the plurality of fourth vias on the substrate;
wherein a number of the third vias that are run through for coupling at the pull-up node is greater than a number of the third vias that are run through for coupling at the coupling node, and a number of the fourth vias that are run through for coupling at the pull-up node is greater than a number of the fourth vias that are run through for coupling at the coupling node.

16. The array substrate according to claim 15, wherein
the number of the third vias that are run through for coupling at the pull-up node is equal to the number of the fourth vias that are run through for coupling at the pull-up node; and
the number of the third vias that are run through for coupling at the coupling node is equal to the number of the fourth vias that are run through for coupling at the coupling node.

17. The array substrate according to claim 15, wherein
the number of the third vias that are run through for coupling at the pull-up node and the number of the fourth vias that are run through for coupling at the pull-up node are both greater than or equal to three and less than or equal to six; and
the number of the third vias that are run through for coupling at the coupling node and the number of the fourth vias that are run through for coupling at the coupling node are both less than or equal to two.

18. The array substrate according to claim 17, wherein
a plurality of the third vias that are run through for coupling at the pull-up node and a plurality of the third vias that are run through for coupling at the coupling node are organized into a plurality of third via groups successively arranged along the second direction, each of the third via groups comprising one of the third vias; and
a plurality of the fourth vias that are run through for coupling at the pull-up node and a plurality of the fourth vias that are run through for coupling at the coupling node are organized into a plurality of fourth via groups successively arranged along the second direction, each of the fourth via groups comprising one of the fourth vias;
wherein the third via groups and the fourth via groups are successively arranged along the first direction.

19. The array substrate according to claim 18, wherein
a number of the plurality of the third vias that are run through for coupling at the pull-up node and a number of the plurality of the fourth vias that are run through for coupling at the pull-up node are both three; and a number of the plurality of the third vias that are run through for coupling at the coupling node and a number of the plurality of the fourth vias that are run through for coupling at the coupling node are both two;
the plurality of the third vias that are run through for coupling at the pull-up node are organized into three of the third via groups successively arranged along the second direction, and the plurality of the fourth vias that are run through for coupling at the pull-up node comprise three of the fourth via groups successively arranged along the second direction; and
the plurality of the third vias that are run through for coupling at the coupling node are organized into two of the third via groups successively arranged along the second direction, and the plurality of the fourth vias that are run through for coupling at the coupling node comprise two of the fourth via groups successively arranged along the second direction.

20. The array substrate according to claim 15, wherein the second connection portion and the common electrode line are disposed in a same layer.

21. (canceled)

22. A display device, comprising: a power supply assembly and an array substrate;
wherein the power supply assembly is coupled to the array substrate and is configured to supply power to the array substrate; and
the array substrate comprises:
a substrate, comprising a display region, a wiring region, and a circuit region, wherein the wiring region and the circuit region are disposed on at least one side of the display region and successively arranged along a direction away from the display region;
a plurality of pixels, disposed in the display region;
a common electrode line, extending along a first direction and disposed in the wiring region, wherein the common electrode line comprises a plurality of cutouts spaced apart and is coupled to the plurality of pixels;
a plurality of gate lines, extending along a second direction and disposed in the display region and the wiring region, wherein the first direction is intersected with the second direction;
a plurality of gate leads, extending along the second direction and disposed in the circuit region and the wiring region, wherein the plurality of gate leads are disposed on a side, distal from the substrate, of the gate line and a side, proximal to the substrate, of the common electrode line; and
a gate drive circuit, disposed in the circuit region and coupled to the plurality of gate leads, wherein the plurality of gate leads are connected to the plurality of gate lines by a connection portion disposed within the cutout, and the plurality of gate lines are coupled to the plurality of pixels.

23. (canceled)
